(19) United States
(12) Patent Application Publication
(10) Pub. No.: US 2026/0214949 A1
(43) Pub. Date: Jul. 23, 2026

(54) SACRIFICIAL STRESSORS FOR APPLYING STRESS TO CHANNEL REGIONS

(71) Applicant: Taiwan Semiconductor Manufacturing Co., Ltd., Hsinchu (TW)

(72) Inventors: Ka-Hing Fung, Zhudong Township (TW); Wei-Yang Lee, Taipei City (TW)

(21) Appl. No.: 19/208,216

(22) Filed: May 14, 2025

Related U.S. Application Data
(60) Provisional application No. 63/748,557, filed on Jan. 23, 2025.

(51) Int. Cl. H10D 30/69; H10D 30/00; H10D 30/01; H10D 30/43; H10D 62/00; H10D 62/10; H10D 64/01; H10D 84/83

(52) U.S. Cl. CPC H10D 30/796; H10D 30/014; H10D 30/0191; H10D 30/43; H10D 30/502; H10D 30/797; H10D 62/021; H10D 62/121; H10D 64/017; H10D 84/832

(57) ABSTRACT

A method includes forming a first multilayer stack and a second multilayer stack. The first multilayer stack comprises a first plurality of sacrificial layers and a first plurality of semiconductor nanostructures located alternatingly. The second multilayer stack comprises a second plurality of sacrificial layers and a second plurality of semiconductor nanostructures located alternatingly. The first plurality of sacrificial layers and the second plurality of sacrificial layers are replaced with a third plurality of sacrificial layers and a fourth plurality of sacrificial layers, respectively. The third plurality of sacrificial layers and the fourth plurality of sacrificial layers are replaced in different processes. Removing the third plurality of sacrificial layers to form first recesses, forming a first gate stack in the first recesses, removing the fourth plurality of sacrificial layers to form second recesses, and forming a second gate stack in the second recesses.

### PRIORITY CLAIM AND CROSS-REFERENCE

This application claims the benefit of the following provisionally filed U.S. Patent application: Application No. 63/748,557, filed on Jan. 23, 2025, and entitled “Semiconductor Structure and method for manufacturing the same,” which application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B and 9 through 22 illustrate the cross-sectional views of intermediate stages in the formation of a die stack in accordance with some embodiments.

FIG. 23 illustrates the difference in dimensions of inner spacers in accordance with some embodiments.

FIG. 24 illustrate the difference in shapes of inner spacers in accordance with some embodiments.

FIG. 25 illustrates a process flow for forming nanostructure transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors (also referred to as nanostructure transistors) and the method of manufacturing the same are provided. In accordance with some embodiments, the sacrificial layers between semiconductor nanostructures are formed as applying a desirable stress to the semiconductor nanostructures, which are channels of the GAA transistors. In accordance with some embodiments, the sacrificial layers in the formation of an n-type GAA transistor is formed as applying a tensile stress to the respective semiconductor nanostructures. During and after the formation of source/drain regions, the stress is memorized by the nanostructures. The sacrificial layers are then removed in order to form a replacement gate stack.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

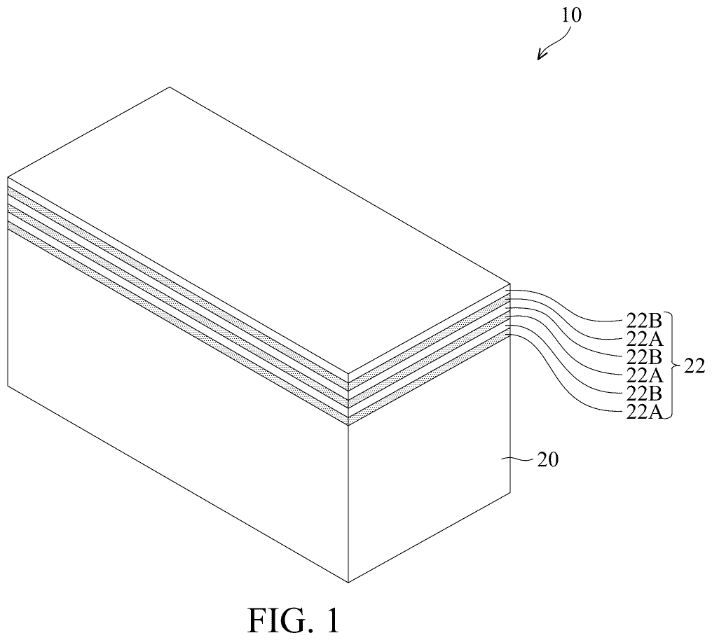

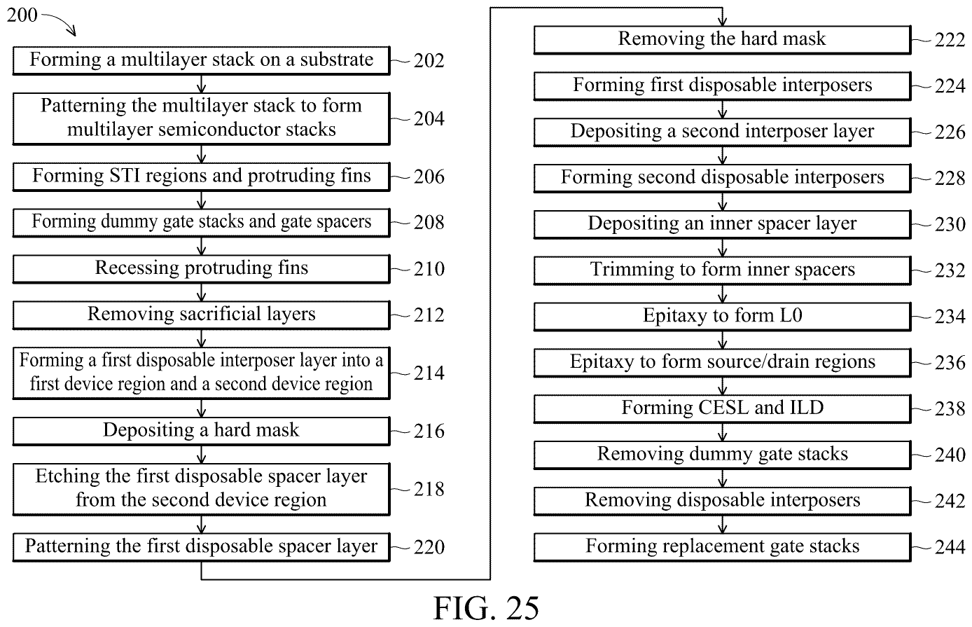

FIGS. 1 through 22 illustrate the cross-sectional views of intermediate stages in the formation of GAA transistors in accordance with some embodiments of the present disclosure. The corresponding processes are also reflected schematically in the process flow shown in FIG. 25.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 as shown in FIG. 25. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of the first layers 22A is formed of or comprises a semiconductor such as SiGe, Ge, Si, GaAs, InSb, GaSb, InAlAs, InGaAs, GaSbP, GaAsSb, or the like. The deposition of first layers 22A (for example, SiGe) may be through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layers 22A are formed to a first thickness in the range between about 30 Å and about 300 Å. However, any suitable thickness may be utilized while remaining within the scope of the embodiments.

In accordance with some embodiments, the second material of the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of the first layers 22A. For example, in accordance with some embodiments in which the first layers 22A are formed of silicon germanium, the second layers 22B may be formed of silicon, or vice versa.

In accordance with some embodiments, the first layers 22A have thicknesses the same as or similar to each other, and the second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

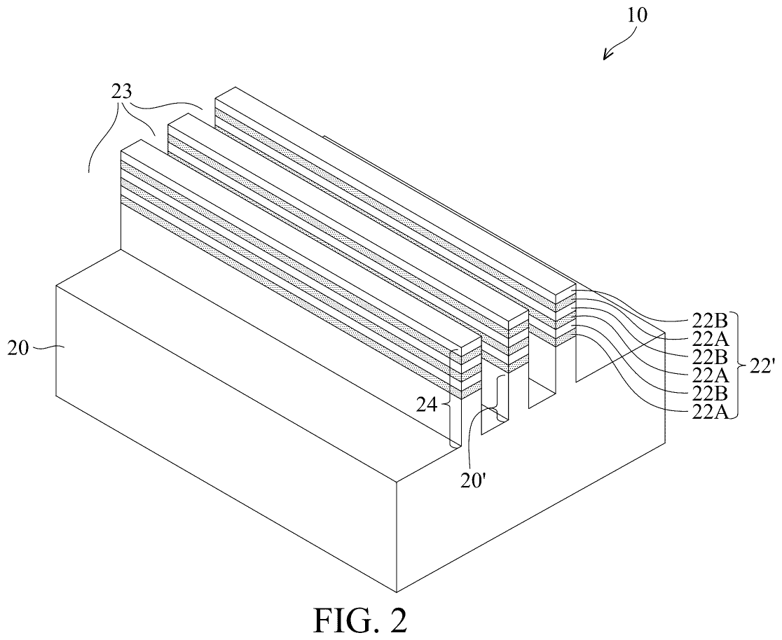

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 25. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

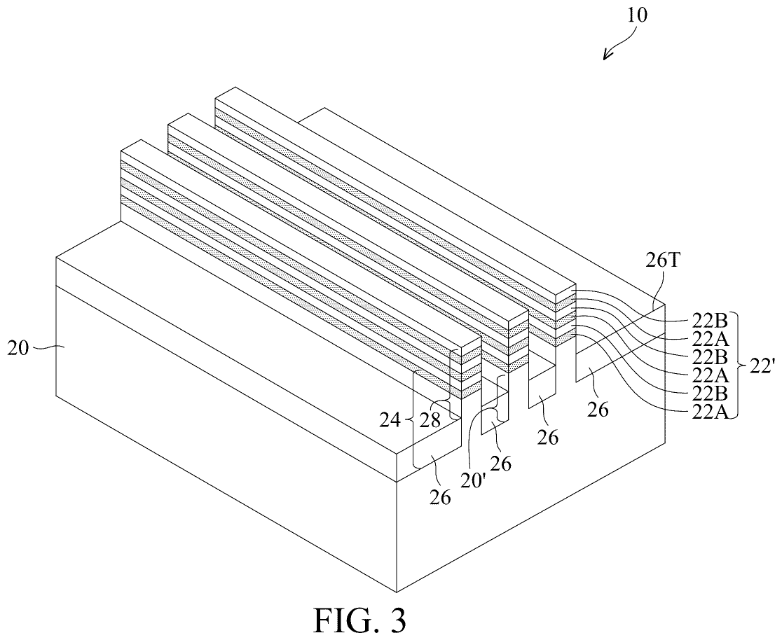

FIG. 3 illustrates the formation of isolation regions 26, which are also referred to as Shallow Trench Isolation (STI) regions throughout the description. The respective process is illustrated as process 206 in the process flow 200 as shown in FIG. 25. STI regions 26 may include a liner oxide (not shown), which may be a thermal oxide formed through the thermal oxidation of a surface layer of substrate 20, or may be deposited. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

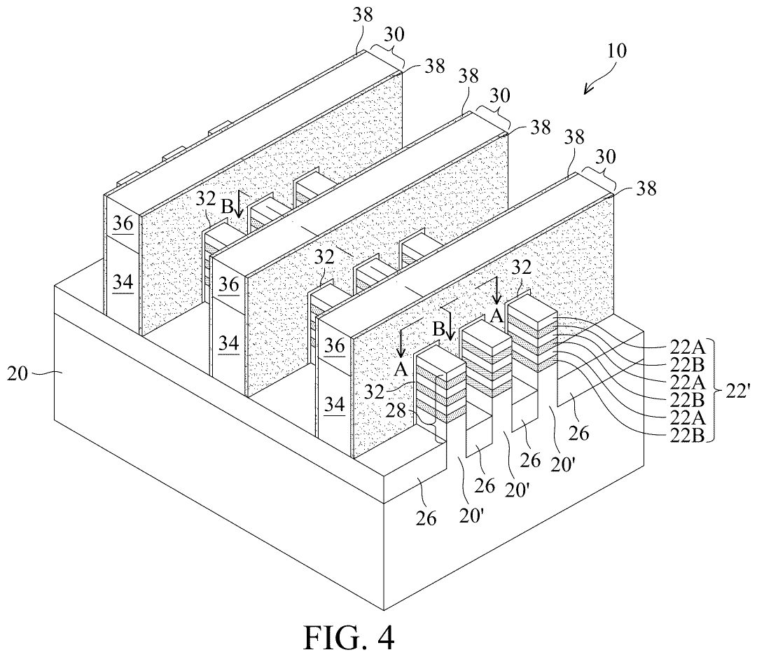

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 25. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

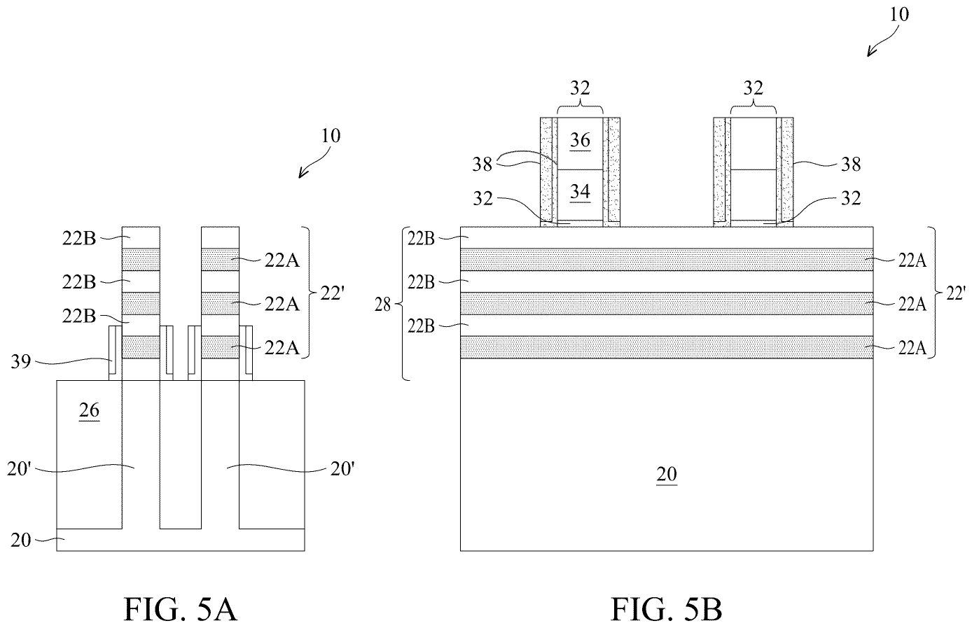

FIGS. 5A and 5B illustrate the cross-sectional views of the structure shown in FIG. 4. FIG. 5A illustrates the reference cross-section A-A in FIG. 4, which cross-section cuts through the portions of protruding fins 28 not covered by gate stacks 30 and gate spacers 38, and is perpendicular to the gate-length direction. Fin spacers 39, which are on the sidewalls of protruding fins 28, are also illustrated. FIG. 5B illustrates the reference cross-section B-B in FIG. 4, which reference cross-section is parallel to the lengthwise directions of protruding fins 28.

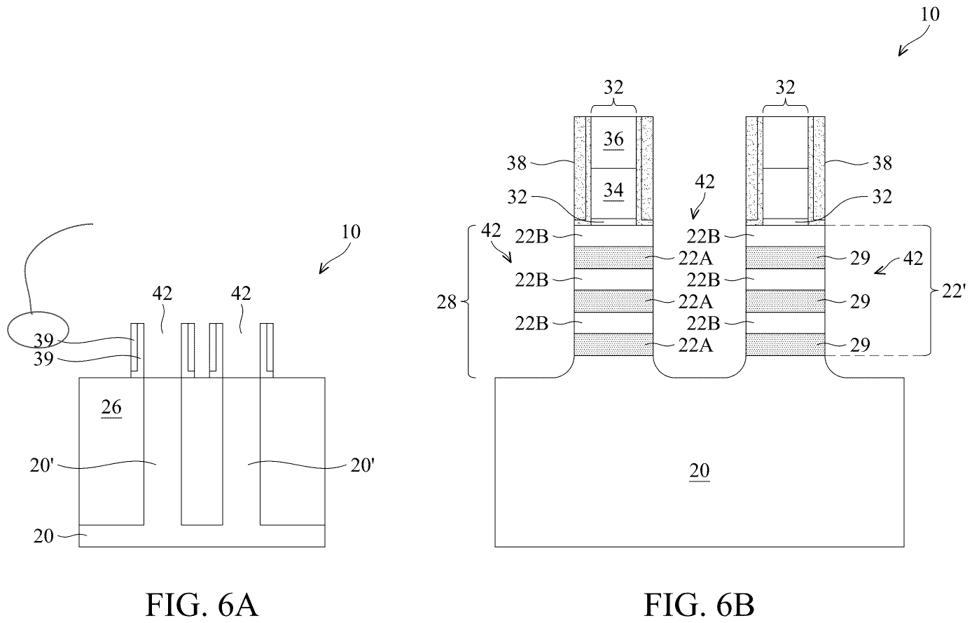

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 as shown in FIG. 25. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight.

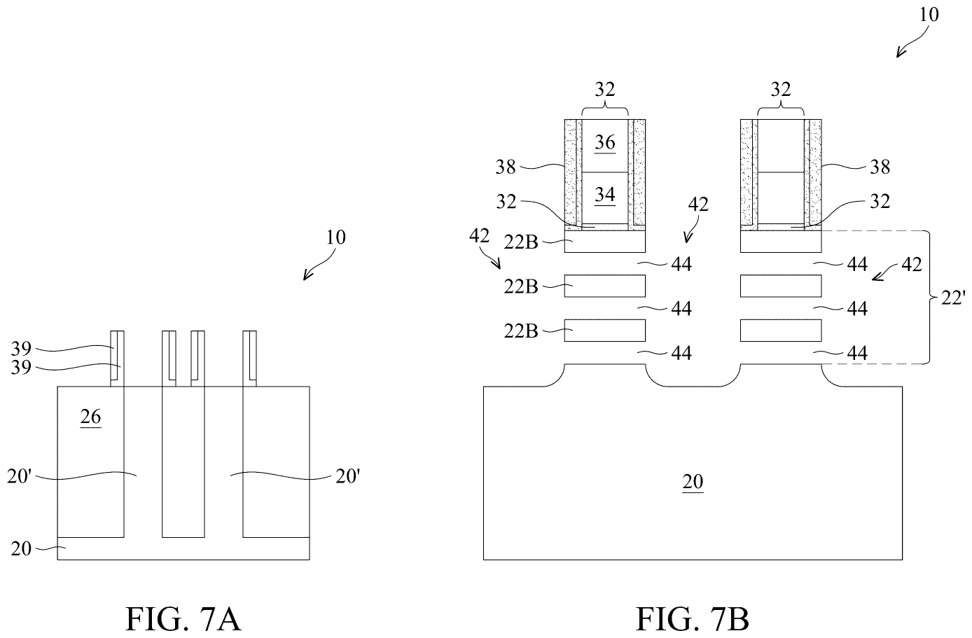

Next, referring to FIGS. 7A and 7B, the sacrificial layers 22A are removed through an etching process, so that spaces 44 are left between neighboring nanostructures 22B. The respective process is illustrated as process 212 in the process flow 200 as shown in FIG. 25. The etching may be performed using an isotropic etching process such as a wet etching process or a dry etching process.

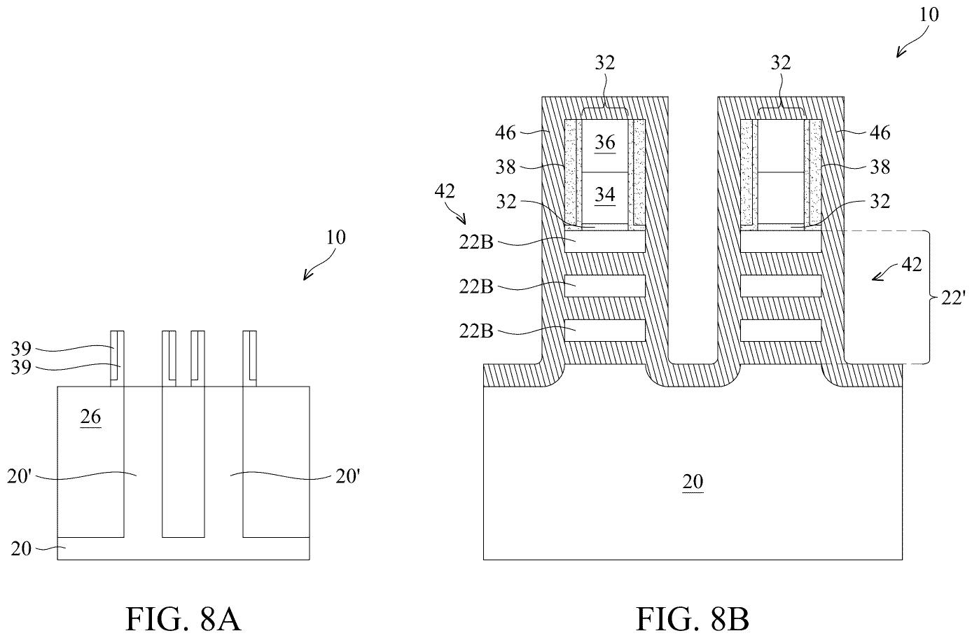

Referring to FIGS. 8A and 8B, (a first) disposable interposer layer 46 is formed to fill the spaces 44 and to separate nanostructures 22B from each other. The respective process is illustrated as process 214 in the process flow 200 as shown in FIG. 25. In accordance with some embodiments, disposable interposer layer 46 comprises an oxide such as silicon oxide, and thus may also be referred to as a disposable oxide interposer layer. In accordance with other embodiments, other types of materials (such as SiON, Al₂O₃, or the like) that do not intermix with nanostructures 22B during the subsequent formation of source/drain regions may be adopted to form the disposable interposers. Disposable interposer layer 46 includes some portions filling the spaces 44 between nanostructures 22B, and some other portions outside of the openings. Disposable interposer layer 46 may be formed using CVD, PECVD, ALD, flowable CVD, or the like.

In accordance with some embodiments, disposable interposer layer 46 may not be used for applying a stress to the respective overlying and underlying nanostructures 22B. For example, the density of disposable interposer layer 46 may be low, such as in the range between about 2.0 gram/cm³ and about 2.6 gram/cm³. The corresponding material may include silicon oxide, for example.

In accordance with alternative embodiments, disposable interposer layer 46 may be used to apply a stress to the nanostructures 22B, and may have a relatively higher density such as in the range between about 2.6 gram/cm³ and about 4.5 gram/cm³. The corresponding material may include TiN, tungsten, and the like.

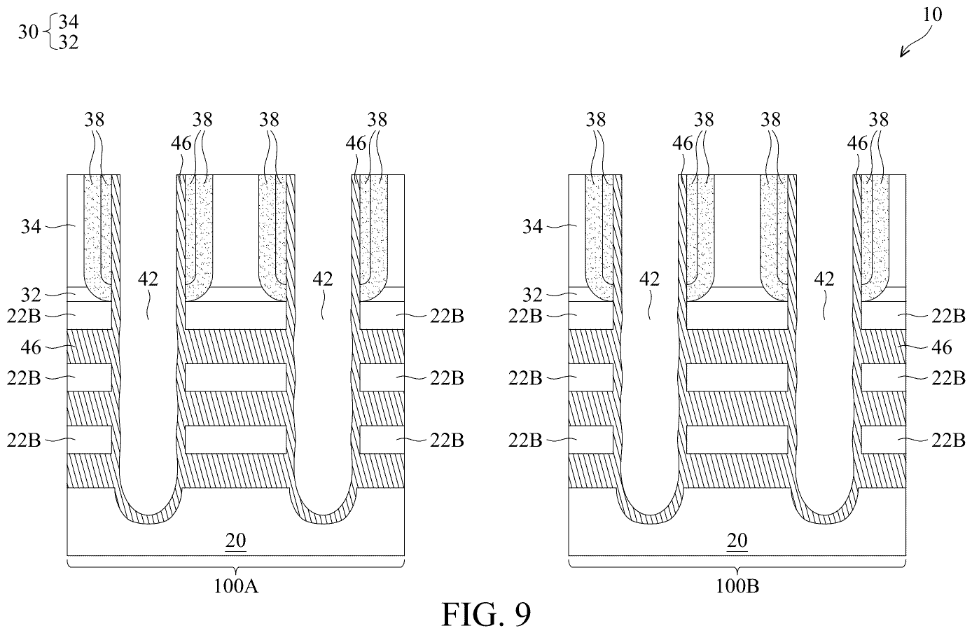

Referring to FIG. 9, in accordance with some embodiments, the wafer 10 (and the device dies therein) includes two device regions 100A and 100B, and disposable interposer layer 46 is deposited into both of device regions 100A and 100B. The structure in each of device regions 100A and 100B may be similar to or essentially the same as shown in FIG. 8B, and is formed using the processes in FIGS. 1 through 8A and 8B. It is appreciated that in FIG. 9 and subsequent figures, features such as disposable interposer layer 46 may include top portions over gate stack 30, and the top portions may not be illustrated.

Each of device regions 100A and 100B may be a p-type device region and an n-type device region, which are used for forming one of p-type transistor and n-type transistor. In subsequent discussion, it is assumed (unless discussed otherwise) that device region 100A is a p-type device region, in which a p-type transistor (PFET) is to be formed, and device region 100B is an n-type device region, in which an n-type transistor (NFET) is to be formed.

In other embodiments, device regions 100A and 100B may also be an n-type device region and a p-type device region, which are used for forming an n-type transistor and a p-type transistor, respectively. In yet other embodiments, both of device regions 100A and 100B may be p-type device regions for forming p-type transistors, or n-type device regions for forming n-type transistors.

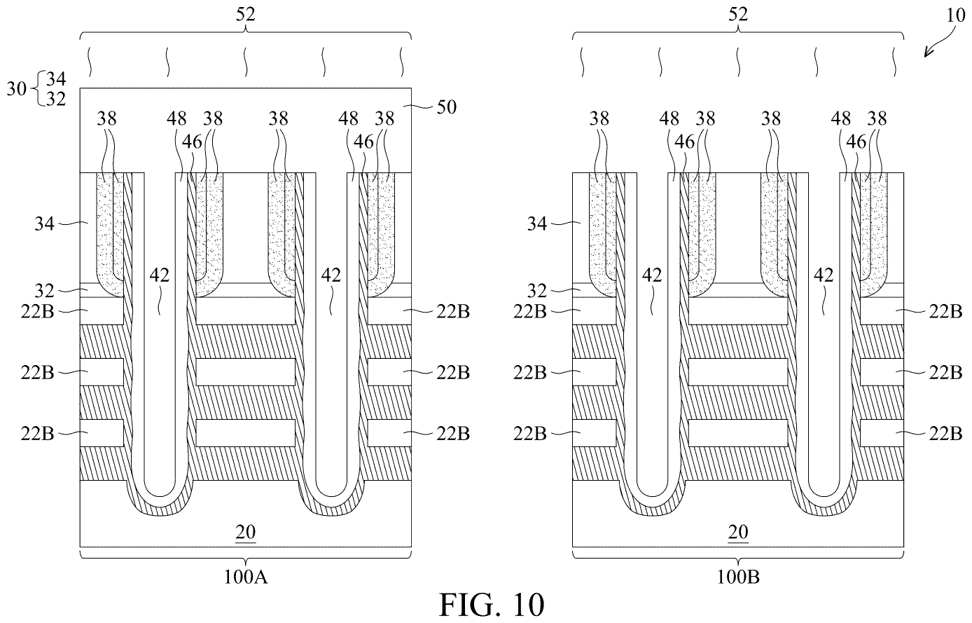

Referring to FIG. 10, hard mask 48 is deposited over disposable interposer layer 46 and in both of device regions 100A and 100B. The respective process is illustrated as process 216 in the process flow 200 as shown in FIG. 25. The hard mask 48 may be formed through a conformal deposition process such as ALD, CVD, or the like. Hard mask 48 may be formed of or comprises silicon nitride, aluminum oxide, or the like.

An etching mask 50, which may include a photoresist, is then formed. Etching mask 50 is patterned, so that the portion of hard mask 48 in device region 100B is exposed through an opening in etching mask 50. A portion of the etching mask 50 in device region 100A is left to cover the underlying portion of hard mask 48.

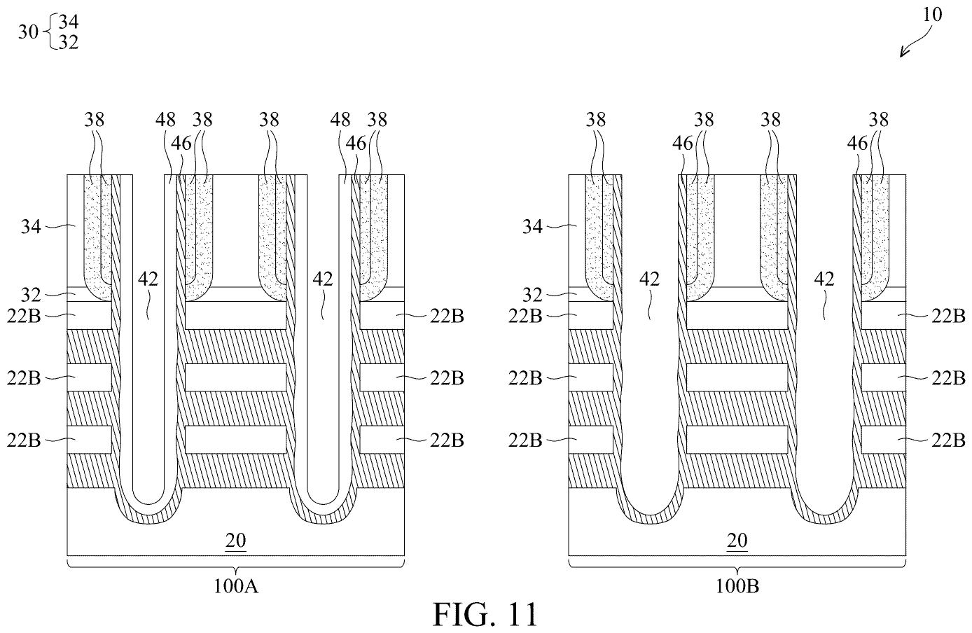

In a subsequent process, as also shown in FIG. 10, etching process 52 is performed to remove the exposed portion of hard mask 48 in device region 100B. The respective process is illustrated as process 218 in the process flow 200 as shown in FIG. 25. Etching mask 50 is then removed. The resulting structure is shown in FIG. 11. The portion of disposable interposer layer 46 in device region 100B is thus exposed, while the portion of disposable interposer layer 46 in device region 100A is protected by hard mask 48.

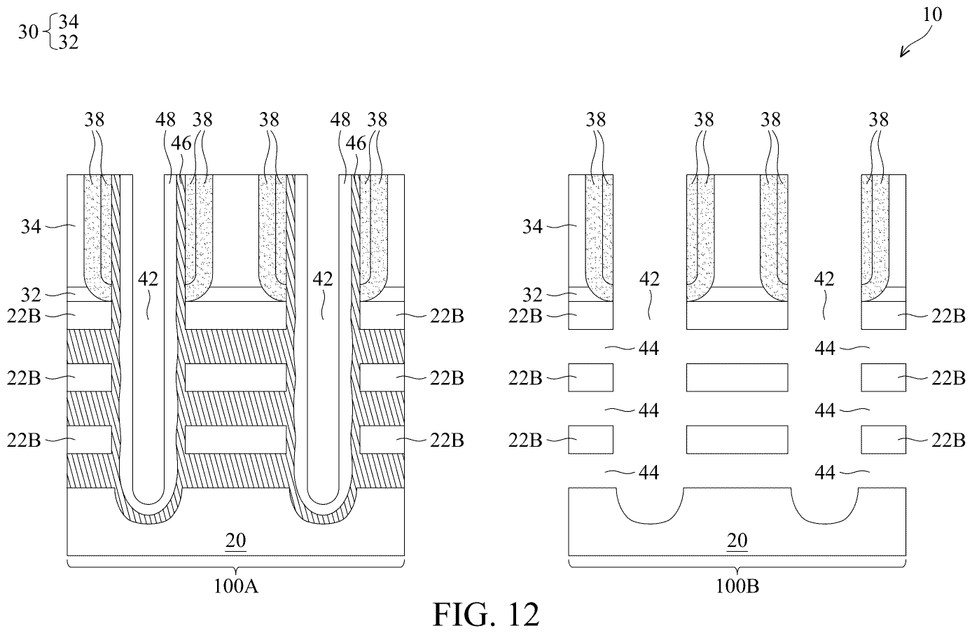

In a subsequent process, an isotropic etching process is performed to remove the exposed portion of disposable interposer layer 46 in device region 100B. The respective process is illustrated as process 220 in the process flow 200 as shown in FIG. 25. Spacings 44 are regenerated between nanostructures 22B. The resulting structure is shown in FIG. 12. In the etching process, hard mask 48 protects the portion of disposable interposer layer 46 in device region 100A from being etched. The etching may be performed through a dry etching process or a wet etching process. For example, when dry etching is used, the mixture of NF₃ and NH₃ or the mixture of HF and NH₃ may be used. When wet etching is performed, an HF solution may be used.

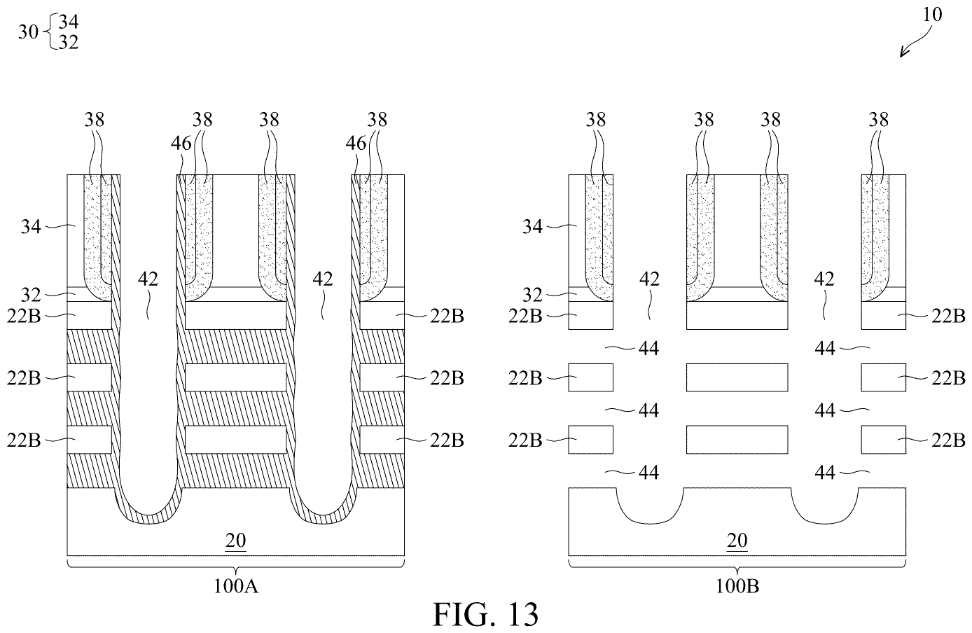

After the etching process, the remaining hard mask 48 is removed, and the resulting structure is shown in FIG. 13. The respective process is illustrated as process 222 in the process flow 200 as shown in FIG. 25.

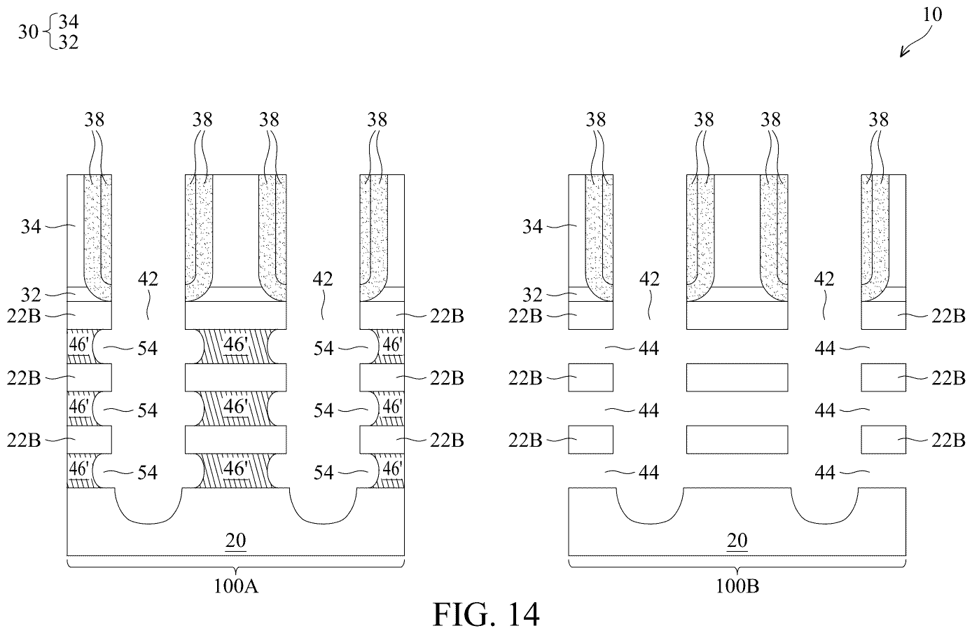

Referring to FIG. 14, an etching process, which may include an anisotropic etching process and/or an isotropic etching process, is performed to trim and laterally recessing disposable interposer layer 46. The remaining portions of the dielectric layer 46 are referred to as disposable interposers 46′. The respective process is illustrated as process 224 in the process flow 200 as shown in FIG. 25. Lateral recesses 54 are thus formed.

The disposable interposers 46′ replace sacrificial layers 22A (FIG. 6B), and thus are alternatively referred to as (replacement) sacrificial layers. When disposable interposers 46′ are formed of an oxide, disposable interposers 46′ may also be referred to as Disposable Oxide Interposers (DOIs) 46′.

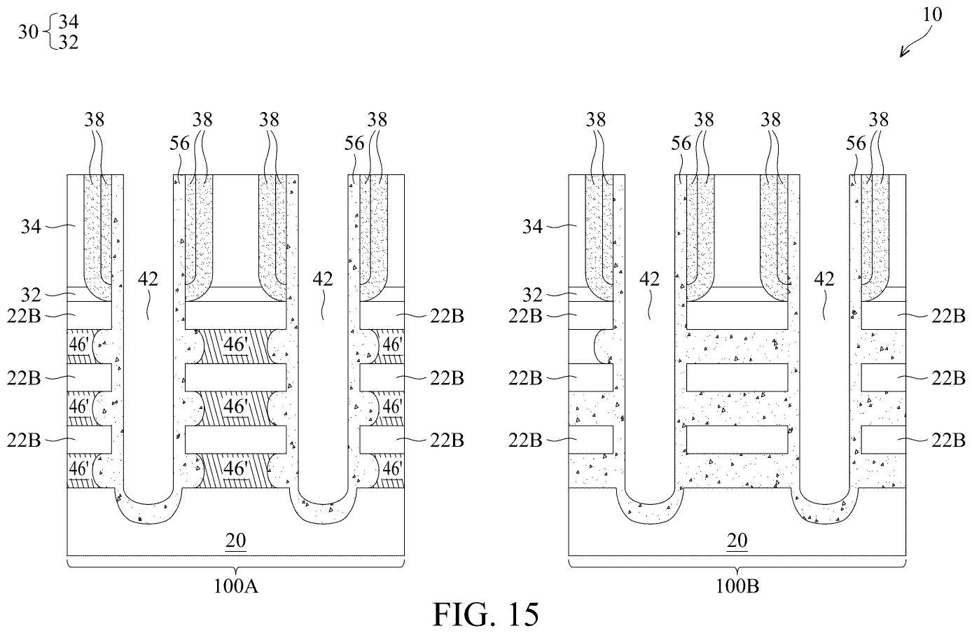

FIG. 15 illustrates the deposition of a (second) disposable spacer layer 56. The respective process is illustrated as process 226 in the process flow 200 as shown in FIG. 25. In accordance with some embodiments, disposable spacer layer 56 is deposited using a method such as ALD, CVD, PECVD, or the like. In device region 100A, disposable interposer layer 56 is formed on disposable interposers 46′ and fills recesses 54 (FIG. 14). In device region 100B, disposable interposer layer 56 fills spaces 44 (FIG. 14).

The disposable spacer layer 56 is configured to apply a different stress to the respective channel regions than disposable interposers 46′ (and disposable spacer layer 46). The difference in stresses may include opposite stress types (with one being compressive and the other being tensile), a same type of stress but of different magnitude, or one being zero stress, while the other being a non-zero stress.

In accordance with some embodiments, a p-type transistor and an n-type transistor are to be formed in device regions 100A and 100B, respectively. Since p-type transistor may use SiGe in the source/drain regions, and SiGe may apply a high stress to the respective channels, the stress (if any) applied by the disposable spacer layer 46 to the channels of the p-type transistor may not have a noticeable improvement to the performance of the p-type transistor. Accordingly, it may not be necessary for disposable spacer layer 46 to apply stress. Disposable spacer layer 46 thus may not apply a stress (or apply a low stress, if any) to the respective channels of the p-type transistor, and thus may be formed to have a low density and a loose structure, so that it can be removed easily.

The source/drain regions of an n-type transistor (for example, formed in device regions 100B), on the other hand, may not be able to apply a high tensile stress to the channels of the n-type transistor. In accordance with some embodiments, disposable spacer layer 56 is configured to apply a tensile stress to the corresponding channels of the n-type transistor.

In accordance with some embodiments, disposable spacer layer 56 may comprise or formed of SiN, TiN, W, or the like. Process conditions such as deposition rate, temperature, the atomic ratios of the elements in these materials, and the like, may be adjusted to apply the desirable stress (such as tensile stress) to the nanostructures 22B in device region 100B.

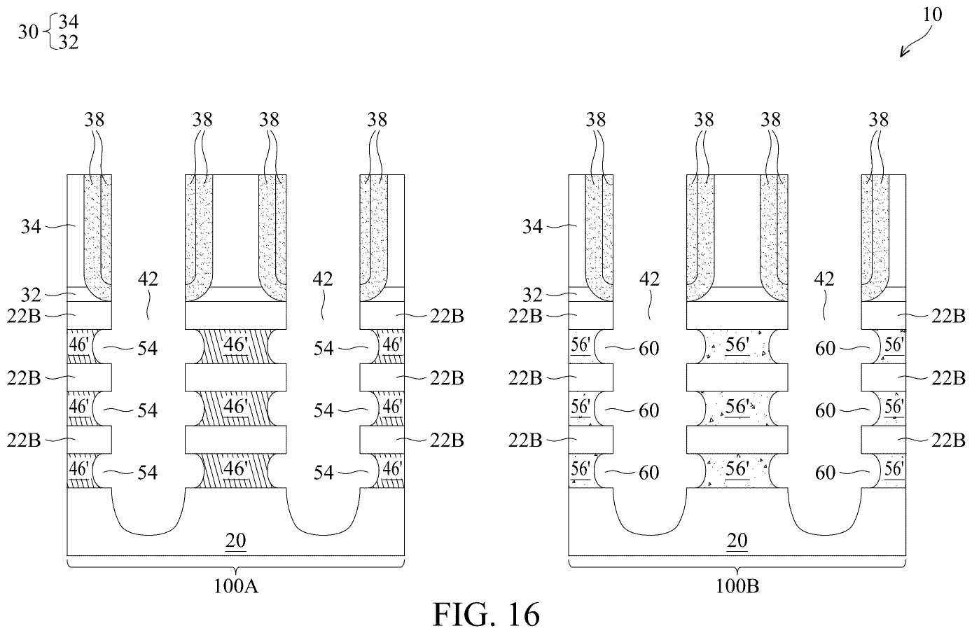

It has been found that the internal stress of the disposable spacer layers 46 and 56 may or may not be the same as the stresses applied by disposable spacers 46′ and 56′ (FIG. 16) to the respective overlying and underlying nanostructures 22B. The stress applied by the bulk materials of disposable spacer layers 46 and 56, which bulk materials are deposited on bulk semiconductor substrates, may also be different from the stresses applied by disposable spacers 46′ and 56′ to the respective overlying and underlying nanostructures 22B.

In accordance with some embodiments, the bonding of disposable spacers 46′ and 56′ to nanostructures 22B may be the primary factors affecting the stress applied to nanostructures 22B. The several atomic layers of bonds between disposable spacers 46′ and 56′ and nanostructures 22B may be the major factor determining the stress type and magnitude. The internal stresses of disposable spacers 46′ and 56′, however, may not be the primary factor affecting the stress applied to the nanostructures 22B. This means that when a tensile stress is applied to the nanostructures 22B, the corresponding overlying/underlying disposable spacers 46′ and 56′ may have an internal tensile stress, an internal compressive stress, or not stress. Similarly, when a compressive stress is applied to the nanostructures 22B, the corresponding overlying/underlying disposable spacers 46′ and 56′ may have an internal tensile stress, an internal compressive stress, or not stress.

Accordingly, when an n-type transistor is to be formed in device region 100B, and when disposable spacer layer 56 applies a tensile stress to the respective overlying/underlying nanostructures 22B in device region 100B, disposable spacer layer 56 itself may be formed as having an internal tensile stress, an internal compressive stress, or no stress.

In order to determine what kind of materials and formation processes may apply a desirable stress to the nanostructures 22B, experiments may be performed to form samples, and the stress in nanostructures 22B may be measured, for example, by using Nano Beam electron Diffraction (NBD) to measure the Si—Si atomic distance, so that the corresponding stress can be determined (calculated). The desirable materials and formation processes for forming disposable interposer layer 56 in order to achieve the desirable stress (such as tensile stress) in nanostructures 22B may thus be determined.

Referring to FIG. 16, an isotropic etching process is performed to remove, trim, and recess disposable interposer layer 56 in device regions 100A and 100B. The respective process is illustrated as process 228 in the process flow 200 as shown in FIG. 25. The etching chemical is selected to etch disposable interposer layer 56, but does not etch disposable interposers 46′. The etching may be performed through a dry etching process or a wet etching process.

In the etching process, the disposable interposer layer 56 in device region 100A is removed. Disposable interposers 46′ are exposed. In device region 100B, disposable interposer layer 56 is trimmed, and the portions of the disposable interposer layer 56 outside of the regions between nanostructures 22B are removed. The remaining portions of the disposable interposer layer 56 are referred to as the disposable interposers 56′, which are also laterally recessed to form lateral recesses 60. The disposable interposers 56′ replace sacrificial layers 22A (FIG. 6B), and thus are alternatively referred to as (replacement) sacrificial layers. When disposable interposers 56′ are formed of an oxide, disposable interposers 56′ may also be referred to as DOIs 56′.

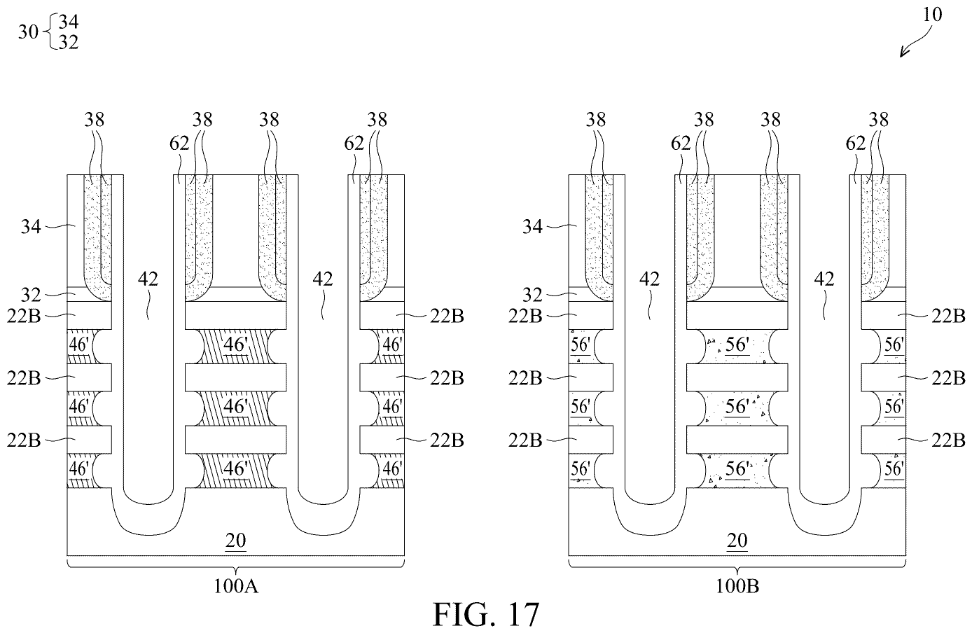

Referring to FIG. 17, inner spacer layer 62 is deposited. The respective process is illustrated as process 230 in the process flow 200 as shown in FIG. 25. The deposition process may comprise a conformal deposition process such as ALD, CVD, or the like. The material of the inner spacer layer 62 is selected to have a good etching selectivity relative to disposable interposers 46′ and 56′. For example, inner spacer layer 62 may comprise silicon oxynitride (SiON), silicon oxycarbonitride (SiOCN), silicon carbo-nitride (SiCN), silicon oxycarbide (SiOC), or the like, while any other suitable material such as low-k materials with a k-value less than about 3.5 may also be utilized. The deposition process is performed until all of lateral recesses 54 and 60 are filled with inner spacer layer 62.

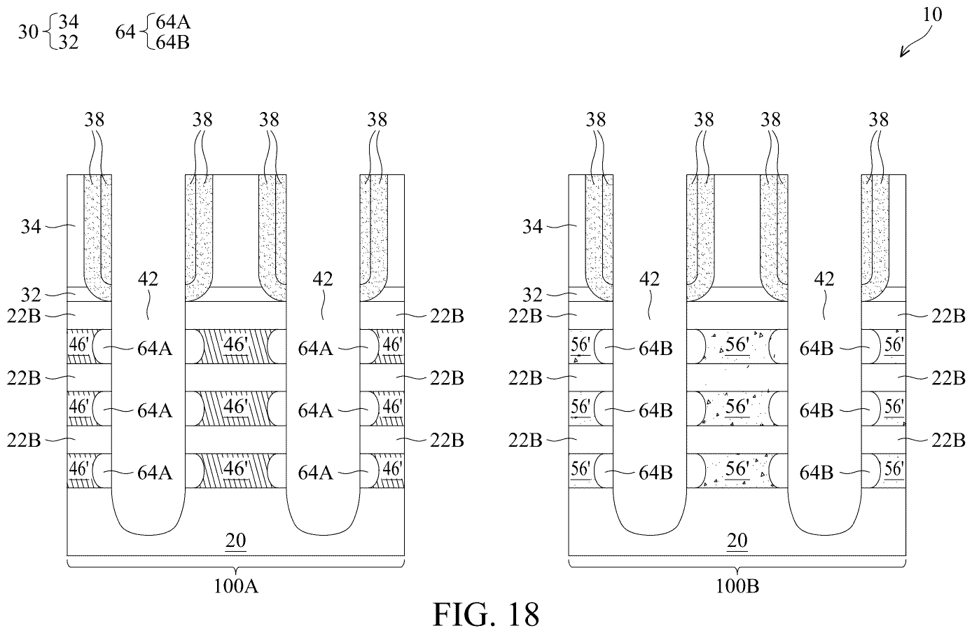

Referring to FIG. 18, a trimming process is performed to trim the portions of inner spacer layer 62. The remaining portions left in lateral recesses 54 and 60 are inner spacers 64A and 64B, respectively. The respective process is illustrated as process 232 in the process flow 200 as shown in FIG. 25. Inner spacers 64A and 64B are also individually and collectively referred to as inner spacers 64.

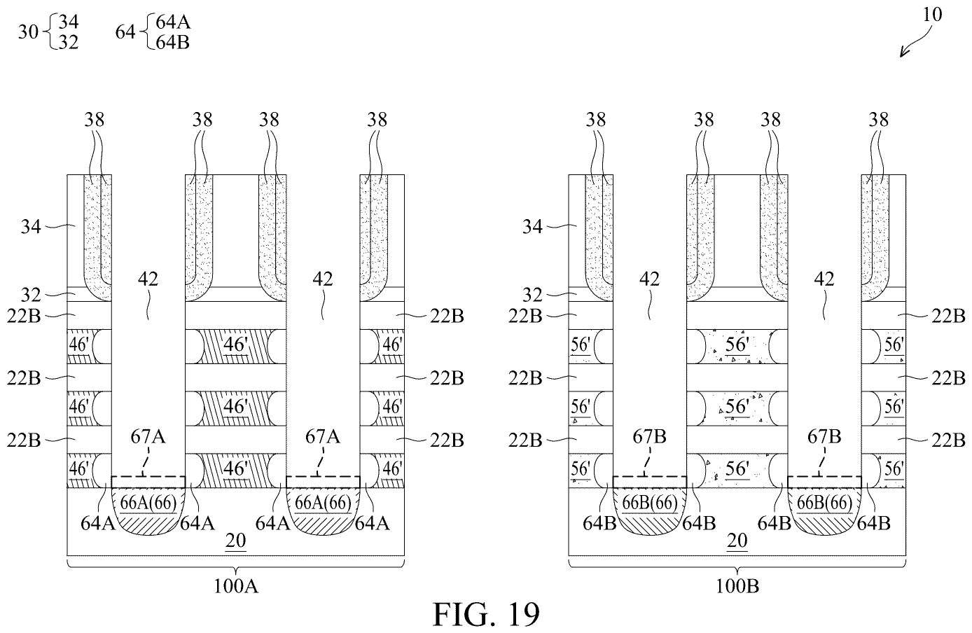

FIG. 19 illustrates the formation of epitaxy isolation regions (also referred to as L0) 66A and 66B in device regions 100A and 100B, respectively. The respective process is illustrated as process 234 in the process flow 200 as shown in FIG. 25. In accordance with some embodiments, epitaxy isolation regions 66A and 66B may be formed of silicon, and may be free from p-type and n-type dopants. In accordance with alternative embodiments, epitaxy isolation regions 66A may be formed of SiGe with a low germanium atomic percentage, for example, lower than about 20 percent. Epitaxy isolation regions 66A may be free from p-type dopants (such as boron), or doped with p-type dopants having a low boron concentration. Epitaxy isolation regions 66B may be formed of Si or carbon-doped silicon. Epitaxy isolation regions 66B may be free from n-type dopants such as phosphorous, or doped with an n-type dopant such as phosphorous with a low phosphorous concentration.

In accordance with some embodiments, dielectric isolation layers 57A and 57B may be formed at the bottoms of the remaining source/drain recesses 42. Alternatively, dielectric isolation layers 57A and 57B are not formed. Accordingly, dielectric isolation layers 57A and 57B are illustrated as being dashed to indicate that dielectric isolation layers 57A and 57B may be formed or not formed.

In accordance with some embodiments, dielectric isolation layers 57A and 57B may comprise silicon nitride (SiN), silicon oxide (SiO), silicon carbide (SiC), silicon oxynitride (SiON), silicon carbo-nitride (SiCN), silicon oxy carbo-nitride (SiOCN), or the like. In accordance with some embodiments, dielectric isolation layers 57A and 57B have a multilayer structure, for example, including a conformal silicon oxide liner and a silicon nitride region over the silicon oxide liner.

In some embodiment, dielectric isolation layers 57A are used in p-type device region 100A and n-type device region 100B, respectively, for reducing current leakage. For some embodiments, dielectric isolation layers 57B are formed in n-type device region 100B, while no dielectric isolation layers are formed in p-type device region 100A. The reason is that dielectric isolation layers may affect the epitaxy of source/drain formation since selective epitaxy regions may not be able to be formed from dielectric materials. Also, p-type transistors prefer to use source/drain regions to provide stress, and it is found that the source/drain regions formed with dielectric isolation layers thereunder may not provide sufficient stress, thus, affecting the efficiency of dielectric isolation layers in providing stress. Accordingly, in some embodiments, the dielectric isolation layers are not formed in p-type device region 100A, but in n-type device region 100B.

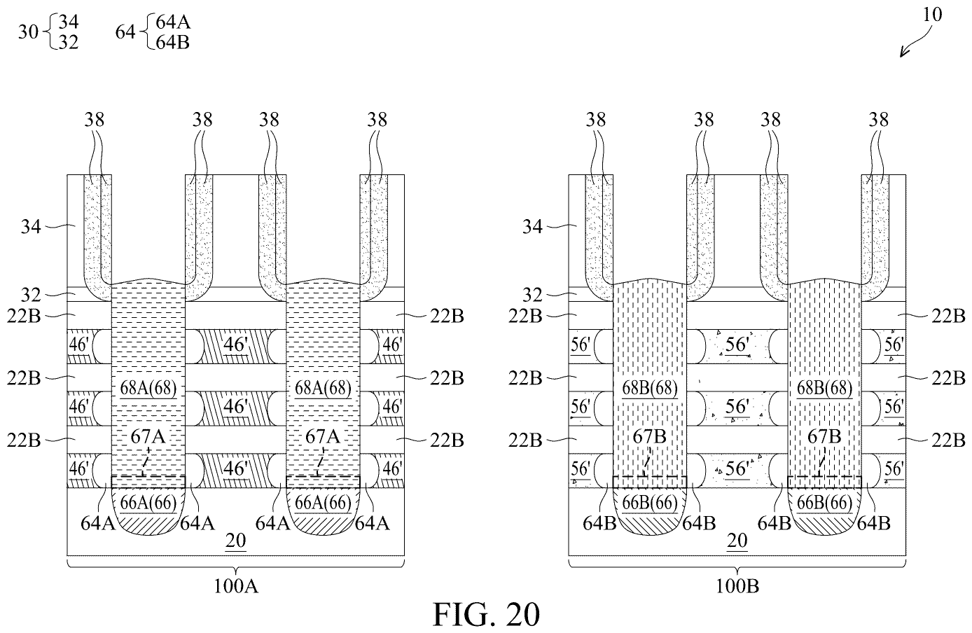

Referring to FIG. 20, epitaxial source/drain regions 68A and 68B are formed in recesses 42 through selective epitaxy. The respective process is illustrated as process 236 in the process flow 200 as shown in FIG. 25. Depending on whether the resulting transistor is a p-type transistor or an n-type transistor, a p-type or an n-type impurity may be in-situ doped with the proceeding of the epitaxy. For example, when the resulting transistor is a p-type transistor, silicon germanium boron (SiGeB), silicon boron (SiB), or the like may be grown. Conversely, when the resulting transistor is an n-type transistor, silicon phosphorous (SiP), silicon carbon phosphorous (SiCP), or the like may be grown. In accordance with some embodiments, epitaxial source/drain regions 68A may be p-type regions, for example, comprising SiGe doped with boron. Epitaxial source/drain regions 68B may be n-type regions, for example, comprising Si or SiC doped with phosphorous.

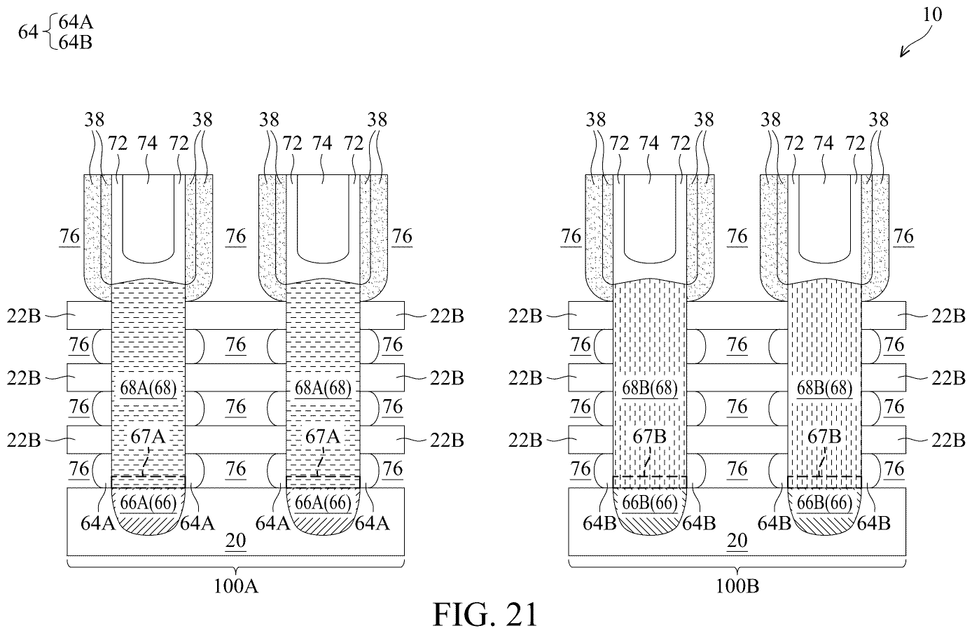

FIG. 21 illustrates the cross-sectional views of the structure after the formation of Contact Etch Stop Layer (CESL) 72 and Inter-Layer Dielectric (ILD) 74. The respective process is illustrated as process 238 in the process flow 200 as shown in FIG. 25. CESL 72 may be formed of silicon oxide, silicon nitride, silicon carbo-nitride, or the like, and may be formed using CVD, ALD, or the like. ILD 74 may include a dielectric material formed using, for example, FCVD, spin-on coating, CVD, or any other suitable deposition method. ILD 74 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like. CESL 72 and ILD 74 are planarized through a planarization process such as a CMP process or a mechanical grinding process.

Next, dummy gate electrodes 34 and dummy gate dielectrics 32 (and hard masks 36, if remaining) are removed in one or more etching processes, so that recesses 76 are formed, as shown in FIG. 21. The respective process is illustrated as process 240 in the process flow 200 as shown in FIG. 25. In accordance with some embodiments, dummy gate electrodes 34 and dummy gate dielectrics 32 are removed through an anisotropic and/or isotropic dry etch process(es). Each recess 76 exposes and/or overlies portions of multilayer stacks 22', which include the future channel regions in subsequently completed transistors.

Disposable interposers 46′ and 56′ (sacrificial layers) are then removed to extend recesses 76 between nanostructures 22B. The respective process is illustrated as process 242 in the process flow 200 as shown in FIG. 25. Disposable interposers 46′ and 56′ may be removed by performing an isotropic etching process(es) such as a dry etching process or a wet etching process using an etchant that is selective to the materials of disposable interposers 46′ and 56′, while nanostructures 22B and substrate 20 remain relatively un-etched as compared to disposable interposers 46′ and 56′. The etching may include a common etching process, in which both of disposable interposers 46′ and 56′ are etched, or separate etching processes, with one for etching interposers 46′, and the other for etching disposable interposers 56′.

It is appreciated that since disposable interposers 46′ and 56′ are removed after the formation of source/drain regions. After the interposers 46′ and 56′ have been removed, the stresses applied by disposable interposers 46′ and 56′ remain in the respective semiconductor nanostructures 22B. For example, when the disposable interposers 56′ are formed as applying a tensile stress to the respective nanostructures 22B in device region 100B, after the removal of disposable interposers 56′, semiconductor nanostructures 22B in device regions 100B have tensile stress memorized therein, and may have a higher stress than the inner stress of source/drain regions 68B.

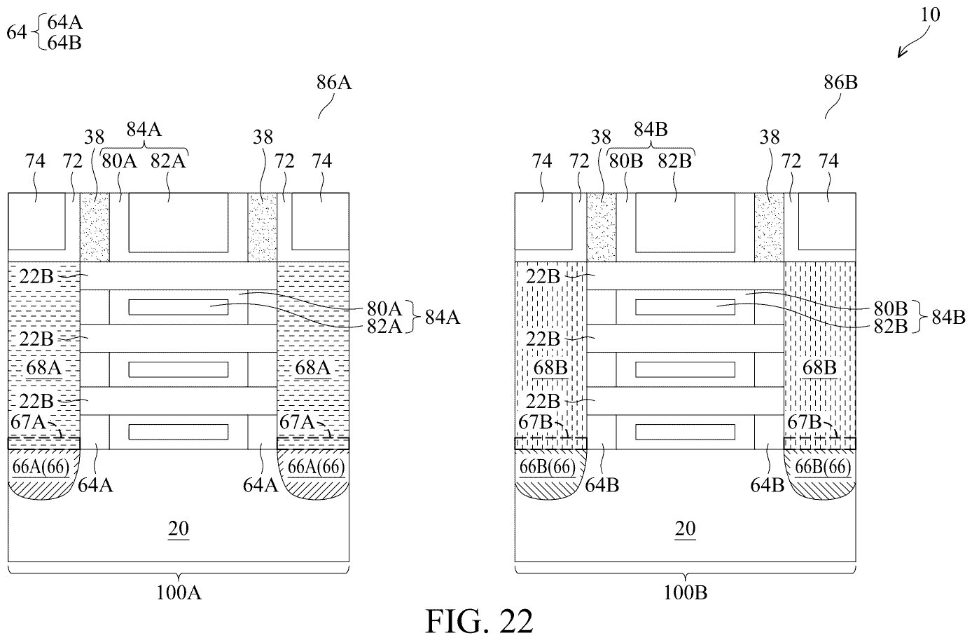

In subsequent processes, replacement gate stacks 84A and 84B are formed. The respective process is illustrated as process 244 in the process flow 200 as shown in FIG. 25. Referring to FIG. 22, gate dielectrics 80 (including gate dielectrics 80A and 80B) are formed. In accordance with some embodiments, each of gate dielectrics 80 includes an interfacial layer and a high-k dielectric layer on the interfacial layer. The interfacial layer may be formed of or comprises silicon oxide, which may be deposited through a conformal deposition process such as ALD or CVD. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 82 (including gate electrodes 82A and 82B) are then formed. In the formation, conductive layers are first formed on the high-k dielectric layer, and fill the remaining portions of recesses 76. Gate electrodes 82 may include a metal-containing material such as TiN, TaN, TiAl, TiAlC, cobalt, ruthenium, aluminum, tungsten, combinations thereof, and/or multilayers thereof. For example, although single-layer gate electrodes 82 are illustrated, gate electrodes 82 may comprise any number of layers, any number of work function layers, and possibly a filling material. Gate dielectrics 80 and gate electrodes 82 also fill the spaces between adjacent ones of nanostructures 22B, and fill the spaces between the bottom ones of nanostructures 22B and the underlying substrate strips 20′.

After the filling of recesses 76, a planarization process such as a CMP process or a mechanical grinding process is performed to remove the excess portions of the gate dielectrics 80 and gate electrodes 82, which excess portions are over the top surface of ILD 74. Gate electrodes 82 and gate dielectrics 80 are collectively referred to as gate stacks 84 (including gate stacks 84A and 84B) of the resulting nano-FETs. GAA transistors 86A and 86B are thus formed.

In accordance with some embodiments in which GAA transistor 86B is an n-type transistor, source/drain regions 68B may have a low internal stress or no internal stress. Gate stacks 84B also have a low internal stress or no internal stress.

It is appreciated that each of the nanostructures 22B (which are channels of the GAA transistor 86B) is fully encircled by a collection of features. The collection of features include gate stack 84B (which encircles the nanostructures 22B when viewed in a vertical cross-section that cuts through nanostructures 22B), source/drain regions 68B, and inner spacers 64B. The collection of features (referred to as 68B/84B/64B) may individually and collectively apply first stresses to the nanostructures 22B. The internal stresses of nanostructures 22B, however, are memorized from the interposers 56′ (which have been removed), and higher than the first stresses. This is a distinctive feature of GAA transistor 86B. The stresses of the collection of features 68B/84B/64B may be determined, for example, by using NBD.

In accordance with some embodiments in which GAA transistor 86A is a p-type transistor, disposable interposers 46′ may apply little or no stress to the channel regions of GAA transistor 86A when disposable interposers 46′ are formed of a loose material, and the compressive stress in channel regions is applied by source/drain regions 68A. Alternatively, disposable interposers 46′ may also apply a compressive stress to the channel regions of GAA transistor 86A, which compressive stress is also memorized in the channel regions at a time after the removal of disposable interposers 46′.

In accordance with alternative embodiments in which both of GAA transistors 86A and 86B are n-type transistors (or compressive stresses), both of disposable interposers 46′ and 56′ may apply tensile stresses (or correspondingly compressive stresses) to the respective channel regions. The magnitude of the stress applied by the disposable interposers 46′ and 56′, however, are different from each other, so that the performance of the GAA transistors 86A and 86B may be tuned.

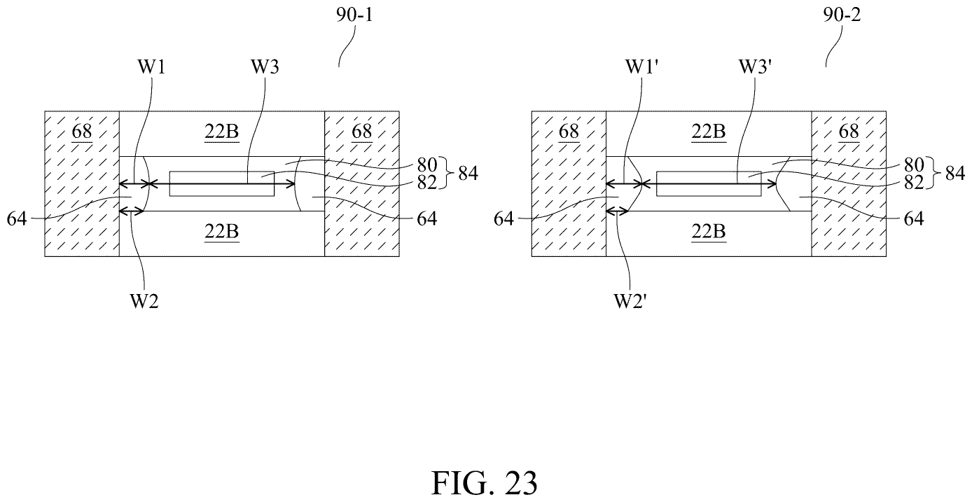

Since the recesses 54 and 60 as shown in FIG. 16 are formed in separate processes, the shapes and lateral dimensions of recesses 54 may be different from or the same as that of recesses 60. For example, FIG. 23 illustrates regions 90-1 and 90-2 of two gate stacks and the surrounding features of two GAA transistors. One of the regions 90-1 and 90-2 may be a part in one of GAA transistors 86A and 86B, and the other is a part in the other one of GAA transistors 86A and 86B. In accordance with some embodiments, region 90-1 is a part of a p-type transistor, and region 90-2 is a part of an n-type transistor. In accordance with alternative embodiments, region 90-1 is a part of an n-type transistor, and region 90-2 is a part of a p-type transistor.

Correspondingly, width W1 may be greater than, equal to, or smaller than width W1′, width W2 may be greater than, equal to, or smaller than width W2′, and width W3 may be greater than, equal to, or smaller than width W3′ in any combination. Widths W1, W2, W1′, and W2′ are the maximum and minimum lateral widths of the inner spacers 64 in regions 90-1 and 90-2. Width W3 and W3′ are the widths of gate stacks 84 in regions 90-1 and 90-2, respectively. For example, there may exist the relationship W1′>W1, W2′<W2, and W3>W3′.

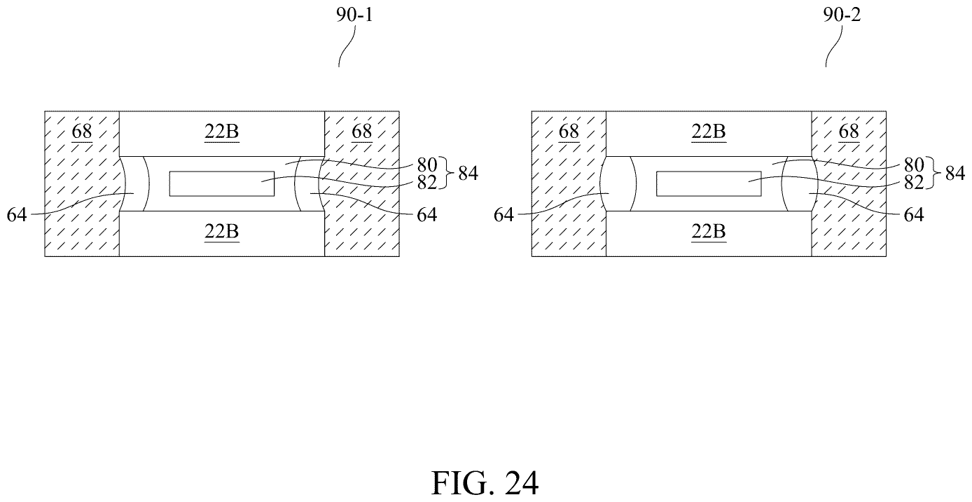

FIG. 24 illustrates the embodiments in which the inner spacers 64 may have same inner sidewall shapes and different outer sidewall shapes. For example, the inner spacers 64 in region 90-1 may have concave outer sidewalls, and the inner spacers 64 in region 90-2 may have convex outer sidewalls.

The embodiments of the present disclosure have some advantageous features. By forming disposable interposers that apply stresses to channel regions of GAA transistors, stress can be memorized in the channel regions. This may particularly be effective in n-type transistors, in which the stresses applied by source/drain regions are usually low. Also, different stresses may be applied to different transistors by different disposable interposers, so that the performance of the transistors may be tuned.

In accordance with some embodiments of the present disclosure, a method comprises forming a first multilayer stack comprising a first plurality of sacrificial layers; and a first plurality of semiconductor nanostructures, wherein the first plurality of sacrificial layers and the first plurality of semiconductor nanostructures are located alternatingly; forming a second multilayer stack comprising a second plurality of sacrificial layers; and a second plurality of semiconductor nanostructures, wherein the second plurality of sacrificial layers and the second plurality of semiconductor nanostructures are located alternatingly; replacing the first plurality of sacrificial layers and the second plurality of sacrificial layers with a third plurality of sacrificial layers and a fourth plurality of sacrificial layers, respectively, wherein the third plurality of sacrificial layers and the fourth plurality of sacrificial layers are replaced in different processes; removing the third plurality of sacrificial layers to form first recesses; forming a first gate stack in the first recesses; removing the fourth plurality of sacrificial layers to form second recesses; and forming a second gate stack in the second recesses.

In an embodiment, the first plurality of sacrificial layers and the second plurality of sacrificial layers comprise silicon germanium, and wherein the third plurality of sacrificial layers comprises silicon oxide. In an embodiment, the third plurality of sacrificial layers have a lower density than the fourth plurality of sacrificial layers. In an embodiment, the fourth plurality of sacrificial layers are configured to apply a tensile stress to the second plurality of semiconductor nanostructures. In an embodiment, the third plurality of sacrificial layers are configured to apply a first stress to the first plurality of semiconductor nanostructures; and the fourth plurality of sacrificial layers are configured to apply a second stress to the second plurality of semiconductor nanostructures, wherein the second stress is greater than the first stress.

In an embodiment, the method further comprises forming a source region and a drain region on opposing sides of the second plurality of semiconductor nanostructures, wherein the fourth plurality of sacrificial layers are removed after the source region and the drain region are formed. In an embodiment, the source region and the drain region have a first internal stress, and the second plurality of semiconductor nanostructures have a second internal stress, and the first internal stress is smaller than the second internal stress.

In an embodiment, the second gate stack has a first internal stress, and the second plurality of semiconductor nanostructures have a second internal stress, and the first internal stress is smaller than the second internal stress. In an embodiment, the method further comprises lateral recessing both of the third plurality of sacrificial layers and the fourth plurality of sacrificial layers to form lateral recesses; and forming inner spacers in the lateral recesses. In an embodiment, the third plurality of sacrificial layers and the fourth plurality of sacrificial layers are laterally recessed in separate etching processes to form the lateral recesses.

In accordance with some embodiments of the present disclosure, a method comprises forming a first plurality of sacrificial layers between a first plurality of semiconductor nanostructures in first formation processes; forming a second plurality of sacrificial layers between a second plurality of semiconductor nanostructures in second formation processes, wherein the first formation processes are separate processes from the second formation processes; forming first source/drain regions on opposing sides of the first plurality of semiconductor nanostructures; forming second source/drain regions on opposing sides of the second plurality of semiconductor nanostructures; in a same etching process, removing the first plurality of sacrificial layers and the second plurality of sacrificial layers to form first recesses and second recesses, respectively, wherein the first plurality of sacrificial layers comprises a different material than the second plurality of sacrificial layers; forming a first gate stack filling the first recesses; and forming a second gate stack filling the second recesses.

In an embodiment, the first source/drain regions are p-type regions, and the second source/drain regions are n-type regions. In an embodiment, the first plurality of sacrificial layers are configured to apply a first stress to the first plurality of semiconductor nanostructures, and the second plurality of sacrificial layers are configured to apply a second stress to the second plurality of semiconductor nanostructures, and wherein the second stress is a tensile stress. In an embodiment, the second plurality of sacrificial layers that apply the tensile stress has an internal compressive stress.

In an embodiment, the second stress has a higher magnitude than the first stress. In an embodiment, the first plurality of sacrificial layers and the second plurality of sacrificial layers are dielectric layers, and the method further comprising replacing semiconductor sacrificial layers with the first plurality of sacrificial layers and the second plurality of sacrificial layers.

In accordance with some embodiments of the present disclosure, a method comprises forming a first transistor comprising forming first semiconductor nanostructure over a semiconductor substrate, wherein the first semiconductor nanostructure has a first internal stress; forming a first source region and a first drain region on opposing sides of, and joined to, the first semiconductor nanostructure, wherein the first source region and the first drain region have a second internal stress smaller than the first internal stress; and forming a first gate stack, wherein the first gate stack comprises a first portion, and wherein in a first cross-section of the first semiconductor nanostructure, the first portion of the first gate stack fully encircles the first semiconductor nanostructure, and wherein the first portion of the first gate stack has a third internal stress smaller than the first internal stress.

In an embodiment, the method further comprises forming a first pair of inner spacers overlying and contacting the first semiconductor nanostructure; and forming a second pair of inner spacers underlying and contacting the first semiconductor nanostructure, wherein the first pair of inner spacers and the second pair of inner spacers have fourth internal stresses smaller than the first internal stress.

In an embodiment, the method further comprises forming a second transistor comprising a second semiconductor nanostructure over the semiconductor substrate; a second source region and a second drain region on opposing sides of, and joined to, the second semiconductor nanostructure, wherein the second source region, the second drain region, and the second semiconductor nanostructure have second internal stresses greater than the first internal stress; and a second gate stack comprising a second portion fully encircling the second semiconductor nanostructure. In an embodiment, the first transistor is an n-type transistor, and the second transistor is a p-type transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first multilayer stack comprising:
a first plurality of sacrificial layers; and
a first plurality of semiconductor nanostructures, wherein the first plurality of sacrificial layers and the first plurality of semiconductor nanostructures are located alternatingly;
forming a second multilayer stack comprising:
a second plurality of sacrificial layers; and
a second plurality of semiconductor nanostructures, wherein the second plurality of sacrificial layers and the second plurality of semiconductor nanostructures are located alternatingly;
replacing the first plurality of sacrificial layers and the second plurality of sacrificial layers with a third plurality of sacrificial layers and a fourth plurality of sacrificial layers, respectively, wherein the third plurality of sacrificial layers and the fourth plurality of sacrificial layers are replaced in different processes;
removing the third plurality of sacrificial layers to form first recesses;
forming a first gate stack in the first recesses;
removing the fourth plurality of sacrificial layers to form second recesses; and
forming a second gate stack in the second recesses.

2. The method of claim 1, wherein the first plurality of sacrificial layers and the second plurality of sacrificial layers comprise silicon germanium, and wherein the third plurality of sacrificial layers comprises silicon oxide.

3. The method of claim 1, wherein the third plurality of sacrificial layers have a lower density than the fourth plurality of sacrificial layers.

4. The method of claim 3, wherein the fourth plurality of sacrificial layers are configured to apply a tensile stress to the second plurality of semiconductor nanostructures.

5. The method of claim 1, wherein:
the third plurality of sacrificial layers are configured to apply a first stress to the first plurality of semiconductor nanostructures; and
the fourth plurality of sacrificial layers are configured to apply a second stress to the second plurality of semiconductor nanostructures, wherein the second stress is greater than the first stress.

6. The method of claim 1 further comprising forming a source region and a drain region on opposing sides of the second plurality of semiconductor nanostructures, wherein the fourth plurality of sacrificial layers are removed after the source region and the drain region are formed.

7. The method of claim 6, wherein the source region and the drain region have a first internal stress, and the second plurality of semiconductor nanostructures have a second internal stress, and the first internal stress is smaller than the second internal stress.

8. The method of claim 1, wherein the second gate stack has a first internal stress, and the second plurality of semiconductor nanostructures have a second internal stress, and the first internal stress is smaller than the second internal stress.

9. The method of claim 1 further comprising:
lateral recessing both of the third plurality of sacrificial layers and the fourth plurality of sacrificial layers to form lateral recesses, wherein the third plurality of sacrificial layers and the fourth plurality of sacrificial layers are laterally recessed in separate etching processes to form the lateral recesses; and
forming inner spacers in the lateral recesses.

10. The method of claim 1, wherein the fourth plurality of sacrificial layers comprise titanium nitride (TiN).

11. A method comprising:
forming a first plurality of sacrificial layers between a first plurality of semiconductor nanostructures in first formation processes;
forming a second plurality of sacrificial layers between a second plurality of semiconductor nanostructures in second formation processes, wherein the first formation processes are separate processes from the second formation processes;
forming first source/drain regions on opposing sides of the first plurality of semiconductor nanostructures;
forming second source/drain regions on opposing sides of the second plurality of semiconductor nanostructures;
in a same etching process, removing the first plurality of sacrificial layers and the second plurality of sacrificial layers to form first recesses and second recesses, respectively, wherein the first plurality of sacrificial layers comprise a different material than the second plurality of sacrificial layers;
forming a first gate stack filling the first recesses; and
forming a second gate stack filling the second recesses.

12. The method of claim 11, wherein the first source/drain regions are p-type regions, and the second source/drain regions are n-type regions.

13. The method of claim 12, wherein the first plurality of sacrificial layers are configured to apply a first stress to the first plurality of semiconductor nanostructures, and the second plurality of sacrificial layers are configured to apply a second stress to the second plurality of semiconductor nanostructures, and wherein the second stress is a tensile stress.

14. The method of claim 13, wherein the second plurality of sacrificial layers comprise titanium nitride.

15. The method of claim 13, wherein the second stress has a higher magnitude than the first stress.

16. The method of claim 11, wherein the first plurality of sacrificial layers and the second plurality of sacrificial layers are dielectric layers, and the method further comprising:
replacing semiconductor sacrificial layers with the first plurality of sacrificial layers and the second plurality of sacrificial layers.

17. A method comprising:
forming a first transistor comprising:
forming first semiconductor nanostructure over a semiconductor substrate, wherein the first semiconductor nanostructure has a first internal stress;
forming a first source region and a first drain region on opposing sides of, and joined to, the first semiconductor nanostructure, wherein the first source region and the first drain region have a second internal stress smaller than the first internal stress; and
forming a first gate stack, wherein the first gate stack comprises a first portion, and wherein in a first cross-section of the first semiconductor nanostructure, the first portion of the first gate stack fully encircles the first semiconductor nanostructure, and wherein the first portion of the first gate stack has a third internal stress smaller than the first internal stress.

18. The method of claim 17 further comprising:
forming a first pair of inner spacers overlying and contacting the first semiconductor nanostructure; and
forming a second pair of inner spacers underlying and contacting the first semiconductor nanostructure, wherein the first pair of inner spacers and the second pair of inner spacers have fourth internal stresses smaller than the first internal stress.

19. The method of claim 17 further comprising forming a second transistor comprising:
a second semiconductor nanostructure over the semiconductor substrate;
a second source region and a second drain region on opposing sides of, and joined to, the second semiconductor nanostructure, wherein the second source region, the second drain region, and the second semiconductor nanostructure have second internal stresses greater than the first internal stress; and
a second gate stack comprising a second portion fully encircling the second semiconductor nanostructure.

20. The method of claim 19, wherein the first transistor is an n-type transistor, and the second transistor is a p-type transistor.
